(19) United States
(12) Patent Application Publication
(10) Pub. No.: US 2026/0018381 A1
(43) Pub. Date: Jan. 15, 2026

(54) ETCHING APPARATUS AND ETCHING METHOD

(71) Applicant: Tokyo Electron Limited, Tokyo (JP)

(72) Inventors: Ung DO, Gyeonggi-do (KR); Suktae KIM, Gyeonggi-do (KR); Jiho PARK, Gyeonggi-do (KR); Sanghoon YOU, Gyeonggi-do (KR)

(73) Assignee: Tokyo Electron Limited, Tokyo (JP)

(21) Appl. No.: 19/333,800

(22) Filed: Sep. 19, 2025

Related U.S. Application Data
(63) Continuation of application No. PCT/JP2024/012209, filed on Mar. 27, 2024.

(30) Foreign Application Priority Data
Mar. 28, 2023 (JP) 2023-050845

(51) Int. Cl. H01J 37/32

(52) U.S. Cl. CPC H01J 37/32146; H01J 37/32091; H01J 37/32449; H01J 37/32862; H01J 2237/3348

(57) ABSTRACT

A placing pedestal on which a substrate is to be mounted is provided in the interior of a chamber. When etching a substrate mounted on the placing pedestal by alternately performing a first step of forming a film on the substrate and a second step of etching the substrate in the chamber, the power source periodically applies, to the placing pedestal, pulsed voltages in which the duty ratio in one cycle is set differently between the first step and the second step.

### CROSS-REFERENCE TO RELATED APPLICATIONS

This application is a continuation of International Application No. PCT/JP2024/012209, filed on Mar. 27, 2024, which claims the benefit of priority of the prior Japanese Patent Application No. 2023-050845, filed on Mar. 28, 2023, the entire contents of each are incorporated herein by reference.

### FIELD

Exemplary embodiments disclosed herein relate to an etching apparatus and an etching method.

### BACKGROUND

US 2017/0125260 A discloses a technology in which etching processes are repeated by applying two types of bias voltage.

The present disclosure provides a technology that stably implements etching with a high aspect ratio.

### SUMMARY

In an embodiment of a present disclosure, an etching apparatus includes: a chamber in an interior of which a placing pedestal on which a substrate is to be mounted is provided; and a power source that, when etching the substrate mounted on the placing pedestal by alternately performing a first step of forming a film on the substrate and a second step of etching the substrate in the chamber, periodically applies, to the placing pedestal, pulsed voltages in which a duty ratio in one cycle is set differently between the first step and the second step.

### BRIEF DESCRIPTION OF DRAWINGS

FIG. 1 is a diagram for describing a configuration example of a plasma processing system;

FIG. 2 is a diagram for describing a configuration example of a capacitively coupled plasma processing apparatus;

FIG. 3 is a diagram describing an example of voltage applied during etching according to an embodiment;

FIG. 4A is a diagram describing an example of etching according to the embodiment;

FIG. 4B is a diagram describing the example of etching according to the embodiment;

FIG. 5A is a diagram describing an example of etching according to a first reference example;

FIG. 5B is a diagram describing the example of etching according to the first reference example;

FIG. 6 is a diagram describing an example of voltage applied during etching according to a second reference example;

FIG. 7A is a diagram illustrating an example of a bias RF signal according to the second reference example;

FIG. 7B is a diagram illustrating an example of a first DC signal according to the embodiment; and

FIG. 8 is a diagram describing an example of a processing order of an etching method according to an embodiment.

### DESCRIPTION OF EMBODIMENTS

Hereinbelow, embodiments of an etching apparatus and an etching method disclosed by the present application are described in detail with reference to the drawings. The disclosed etching apparatus and etching method are not limited by the present embodiments.

Meanwhile, with increase in integration and miniaturization of semiconductor devices, the aspect ratio of a pattern formed on a semiconductor wafer is increased, and recesses of the pattern are deepened. Accordingly, in plasma etching, it is required to stably implement etching with a high aspect ratio.

### Embodiments

### Device Configuration

An example of a plasma processing apparatus of the present disclosure will now be described. In the embodiment described below, a case where the etching apparatus of the present disclosure is configured as a plasma processing system of a system configuration is described as an example.

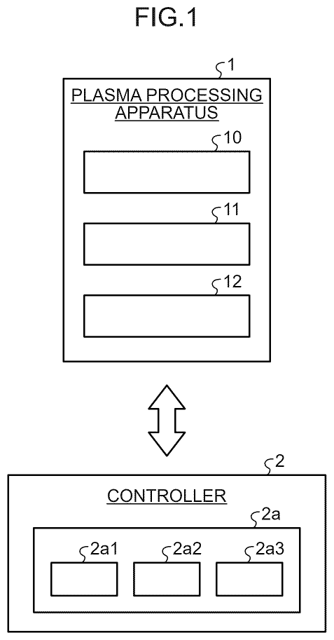

FIG. 1 is a diagram for describing a configuration example of a plasma processing system. In an embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support unit 11, and a plasma generation unit 12. The plasma processing chamber 10 has a plasma processing space. Further, the plasma processing chamber 10 has at least one gas supply port for supplying at least one processing gas to the plasma processing space and at least one gas discharge port for discharging gas from the plasma processing space. The gas supply port is connected to a gas supply unit 20 described later, and the gas discharge port is connected to an exhaust system 40 described later. The substrate support unit 11 is placed in the plasma processing space, and has a substrate support surface for supporting a substrate.

The plasma generation unit 12 is configured to generate plasma from at least one processing gas supplied into the plasma processing space. The plasma formed in the plasma processing space may be capacitively coupled plasma (CCP), inductively coupled plasma (ICP), electron-cyclotron-resonance (ECR) plasma), helicon wave plasma (HWP), surface wave plasma (SWP), or the like. Further, various types of plasma generation units including an alternating current (AC) plasma generation unit and a direct current (DC) plasma generation unit may be used. In an embodiment, an AC signal (AC power) used in the AC plasma generation unit has a frequency in the range of 100 kHz to 10 GHZ. Thus, the AC signal includes a radio frequency (RF) signal and a microwave signal. In an embodiment, the RF signal has a frequency in the range of 100 kHz to 150 MHZ.

The controller 2 processes computer-executable instructions that cause the plasma processing apparatus 1 to execute various processes described in the present disclosure. The controller 2 can be configured to control the elements of the plasma processing apparatus 1 so that the elements execute various processes described herein. In an embodiment, part or the whole of the controller 2 may be included in the plasma processing apparatus 1. The controller 2 may include a processing unit 2a1, a storage unit 2a2, and a communication interface 2a3. The controller 2 is obtained with (i.e., implemented with), for example, a computer 2a. The processing unit 2a1 can be configured to perform various control operations by reading a program from the storage unit 2a2 and executing the read program. This program may be stored in the storage unit 2a2 in advance, or may be acquired via a medium when necessary. The acquired program is stored in the storage unit 2a2, and is read from the storage unit 2a2 and executed by the processing unit 2a1. The medium may be any of various storage media readable by the computer 2a, or may be a communication line connected to the communication interface 2a3. The processing unit 2a1 may be a central processing unit (CPU). The storage unit 2a2 may include a random-access memory (RAM), a read-only memory (ROM), a hard disk drive (HDD), a solid-state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICS (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

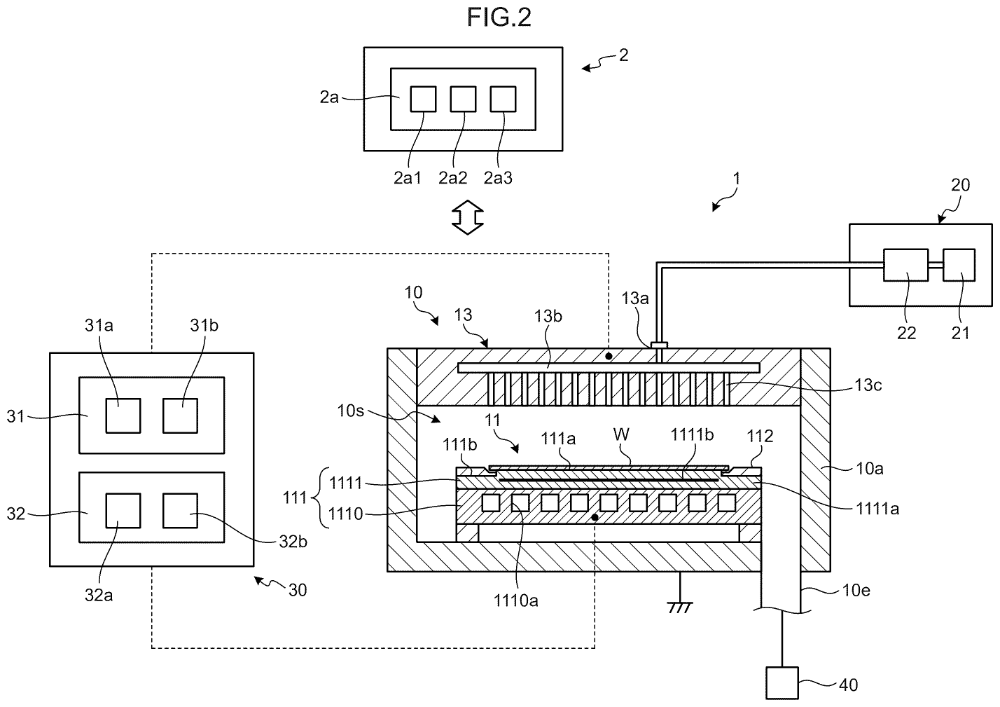

A configuration example of a capacitively coupled plasma processing apparatus as an example of the plasma processing apparatus 1 will now be described. FIG. 2 is a diagram for describing a configuration example of a capacitively coupled plasma processing apparatus.

A capacitively coupled plasma processing apparatus 1 includes a plasma processing chamber 10, a gas supply unit 20, a power source 30, and an exhaust system 40. Further, the plasma processing apparatus 1 includes a substrate support unit 11 and a gas introduction unit. The gas introduction unit is configured to introduce at least one processing gas into the plasma processing chamber 10. The gas introduction unit includes a shower head 13. The substrate support unit 11 is placed in the plasma processing chamber 10. The shower head 13 is placed above the substrate support unit 11. In an embodiment, the shower head 13 forms at least part of the ceiling of the plasma processing chamber 10. The plasma processing chamber 10 has a plasma processing space 10s defined by the shower head 13, a side wall 10a of the plasma processing chamber 10, and the substrate support unit 11. The plasma processing chamber 10 is grounded. The shower head 13 and the substrate support unit 11 are electrically insulated from the housing of the plasma processing chamber 10.

The substrate support unit 11 includes a main body unit 111 and a ring assembly 112. The main body unit 111 has a central region 111a for supporting a substrate W and an annular region 111b for supporting the ring assembly 112. A wafer is an example of the substrate W. In a planar view, the annular region 111b of the main body unit 111 surrounds the central region 111a of the main body unit 111. The substrate W is placed on the central region 111a of the main body unit 111, and the ring assembly 112 is placed on the annular region 111b of the main body unit 111 in such a way as to surround the substrate W on the central region 111a of the main body unit 111. Thus, the central region 111a is referred to also as a substrate support surface for supporting the substrate W, and the annular region 111b is referred to also as a ring support surface for supporting the ring assembly 112.

In an embodiment, the main body unit 111 includes a base 1110 and an electrostatic chuck 1111. The base 1110 includes a conductive member. The conductive member of the base 1110 can function as a bottom electrode. The electrostatic chuck 1111 is placed on the base 1110. The electrostatic chuck 1111 includes a ceramic member 1111a and an electrostatic electrode 1111b placed in the ceramic member 1111a. The ceramic member 1111a has the central region 111a. In an embodiment, the ceramic member 1111a has also the annular region 111b. For the annular region 111b, another member surrounding the electrostatic chuck 1111, such as an annular electrostatic chuck or an annular insulating member, may have the annular region 111b. In this case, the ring assembly 112 may be placed on the annular electrostatic chuck or the annular insulating member, or may be placed on both the electrostatic chuck 1111 and the annular insulating member. Further, at least one RF/DC electrode coupled to an RF power source 31 and/or a DC power source 32 described later may be placed in the ceramic member 1111a. In this case, the at least one RF/DC electrode functions as a bottom electrode. In the case where a bias RF signal and/or a DC signal described later is supplied to at least one RF/DC electrode, the RF/DC electrode is referred to also as a bias electrode. The conductive member of the base 1110 and at least one RF/DC electrode may function as a plurality of bottom electrodes. Further, the electrostatic electrode 1111b may function as a bottom electrode. Thus, the substrate support unit 11 includes at least one bottom electrode.

The ring assembly 112 includes one or a plurality of annular members. In an embodiment, the one or plurality of annular members include one or a plurality of edge rings and at least one cover ring. The edge ring is formed of a conductive material or an insulating material, and the cover ring is formed of an insulating material.

The substrate support unit 11 may include a temperature adjustment module configured to regulate at least one of the electrostatic chuck 1111, the ring assembly 112, and the substrate to a target temperature. The temperature adjustment module may include a heater, a heat transfer medium, a flow channel 1110a, or a combination thereof. A heat transfer fluid such as brine or gas flows through the flow channel 1110a. In an embodiment, a flow channel 1110a is formed in the base 1110, and one or a plurality of heaters are placed in the ceramic member 1111a of the electrostatic chuck 1111. The substrate support unit 11 may include a heat transfer gas supply unit configured to supply heat transfer gas to a gap between the back surface of the substrate W and the central region 111a.

The shower head 13 is configured to introduce at least one processing gas from the gas supply unit 20 into the plasma processing space 10s. The shower head 13 has at least one gas supply port 13a, at least one gas diffusion chamber 13b, and a plurality of gas introduction ports 13c. Processing gas supplied to the gas supply port 13a passes through the gas diffusion chamber 13b, and is introduced from the plurality of gas introduction ports 13c into the plasma processing space 10s. Further, the shower head 13 includes at least one top electrode. The gas introduction unit may include, in addition to the shower head 13, one or a plurality of side gas injectors (SGI) attached to one or a plurality of openings formed in the side wall 10a.

The gas supply unit 20 may include at least one gas source 21 and at least one flow rate controller 22. In an embodiment, the gas supply unit 20 is configured to supply at least one processing gas from the corresponding gas source 21 to the shower head 13 via the corresponding flow rate controller 22. Each flow rate controller 22 may include, for example, a mass flow controller or a pressure control-type flow rate controller. Further, the gas supply unit 20 may include at least one flow rate modulation device that modulates or pulses the flow rate of at least one processing gas.

The power source 30 includes an RF power source 31 coupled to the plasma processing chamber 10 via at least one impedance matching circuit. The RF power source 31 is configured to supply at least one RF signal (RF power) to at least one bottom electrode and/or at least one top electrode. Thereby, plasma is formed from at least one processing gas supplied to the plasma processing space 10s. Thus, the RF power source 31 can function as at least part of the plasma generation unit 12. Further, by supplying a bias RF signal to at least one bottom electrode, a bias potential is generated in the substrate W, and an ion component in the formed plasma can be drawn into the substrate W.

In an embodiment, the RF power source 31 includes a first RF generation unit 31a and a second RF generation unit 31b. The first RF generation unit 31a is coupled to at least one bottom electrode and/or at least one top electrode via at least one impedance matching circuit, and is configured to generate a source RF signal (source RF power) for plasma generation. In an embodiment, the source RF signal has a frequency in the range of 10 MHZ to 150 MHZ. In an embodiment, the first RF generation unit 31a may be configured to generate a plurality of source RF signals having different frequencies. The generated one or plurality of source RF signals are supplied to at least one bottom electrode and/or at least one top electrode.

The second RF generation unit 31b is coupled to at least one bottom electrode via at least one impedance matching circuit, and is configured to generate a bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in the range of 100 kHz to 60 MHZ. In an embodiment, the second RF generation unit 31b may be configured to generate a plurality of bias RF signals having different frequencies. The generated one or plurality of bias RF signals are supplied to at least one bottom electrode. In various embodiments, at least one of the source RF signal and the bias RF signal may be pulsed.

The power source 30 may include a DC power source 32 coupled to the plasma processing chamber 10. The DC power source 32 includes a first DC generation unit 32a and a second DC generation unit 32b. In an embodiment, the first DC generation unit 32a is connected to at least one bottom electrode, and is configured to generate a first DC signal. The generated first DC signal is applied to at least one bottom electrode. In an embodiment, the second DC generation unit 32b is connected to at least one top electrode, and is configured to generate a second DC signal. The generated second DC signal is applied to at least one top electrode.

In various embodiments, the first and second DC signals may be pulsed. In this case, a sequence of voltage pulses is applied to at least one bottom electrode and/or at least one top electrode. The voltage pulse may have a pulse waveform of a rectangle, a trapezoid, a triangle, or a combination thereof. In an embodiment, a waveform generation unit for generating a sequence of voltage pulses from a DC signal is connected between the first DC generation unit 32a and at least one bottom electrode. Thus, the first DC generation unit 32a and the waveform generation unit constitute a voltage pulse generation unit. In the case where the second DC generation unit 32b and a waveform generation unit constitute a voltage pulse generation unit, the voltage pulse generation unit is connected to at least one top electrode. The voltage pulse may have a positive polarity or a negative polarity. The sequence of voltage pulses may include, in one cycle, one or a plurality of positive voltage pulses and one or a plurality of negative voltage pulses. The first and second DC generation units 32a and 32b may be provided in addition to the RF power source 31, or the first DC generation unit 32a may be provided in place of the second RF generation unit 31b.

In the present embodiment, during plasma processing, the plasma processing apparatus 1 supplies a source RF signal for plasma generation from the first RF generation unit 31a to the top electrode of the shower head 13, the bottom electrode of the base 1110 included in the substrate support unit 11, or the bottom electrode provided in the electrostatic chuck 1111. Further, during plasma processing, the plasma processing apparatus 1 applies a pulsed first DC signal from the first DC generation unit 32a to the bottom electrode of the base 1110. During plasma processing, the plasma processing apparatus 1 may apply a second DC signal from the second DC generation unit 32b to the top electrode of the shower head 13. The first DC generation unit 32a is configured to be able to change the duty ratio in one cycle of the pulsed first DC signal. For example, the first DC generation unit 32a is configured to be able to, according to control from the controller 2, change the ratio in one cycle of the period in which the first DC signal is on.

The exhaust system 40 can be connected to, for example, a gas discharge port 10e provided in a bottom portion of the plasma processing chamber 10. The exhaust system 40 may include a pressure adjustment valve and a vacuum pump. The pressure in the plasma processing space 10s is adjusted by the pressure adjustment valve. The vacuum pump may include a turbomolecular pump, a dry pump, or a combination thereof.

The operation of the plasma processing apparatus 1 configured as above is comprehensively controlled by the controller 2 described above.

The controller 2 controls plasma etching. For example, the controller 2 controls the exhaust system 40 to exhaust the interior of the plasma processing chamber 10 to a predetermined degree of vacuum. The controller 2 controls the gas supply unit 20 to introduce processing gas for etching from the gas supply unit 20 into the plasma processing space 10s. The controller 2 controls the power source 30 to, in accordance with the introduction of processing gas, supply power from the power source 30 and generate plasma in the plasma processing chamber 10, and performs etching on the substrate W.

Meanwhile, miniaturization of a pattern formed on the substrate W has progressed, and in plasma etching it is required to stably implement etching with a high aspect ratio.

Thus, in the present embodiment, the plasma processing apparatus 1 etches the substrate W by alternately performing a first step of forming a film on the substrate W and a second step of etching the substrate W. For example, the controller 2 controls the gas supply unit 20 to set one or both of the type and the flow rate of processing gas differently between the first step and the second step. For example, during the first step, processing gas for film formation is introduced from the gas supply unit 20, and during the second step, processing gas for etching is introduced from the gas supply unit 20. Examples of the processing gas for film formation include a carbon-containing gas. Examples of the processing gas for etching include a fluorine-containing gas and an oxygen-containing gas. Between the first step and the second step, a step of purging (exhausting) processing gas in the plasma processing chamber 10 may be provided. Then, the controller 2 controls the power source 30 to, in the first step and the second step, apply a source RF signal for plasma generation from the first RF generation unit 31a and a pulsed first DC signal from the first DC generation unit 32a to the top electrode of the shower head 13, the bottom electrode of the base 1110, or the bottom electrode provided in the electrostatic chuck 1111. For example, the controller 2 controls the power source 30 to apply a source RF signal for plasma generation and a pulsed first DC signal to the bottom electrode of the base 1110. Further, the controller 2 controls the power source 30 to, in the first step and the second step, apply a second DC signal from the second DC generation unit 32b to the top electrode of the shower head 13.

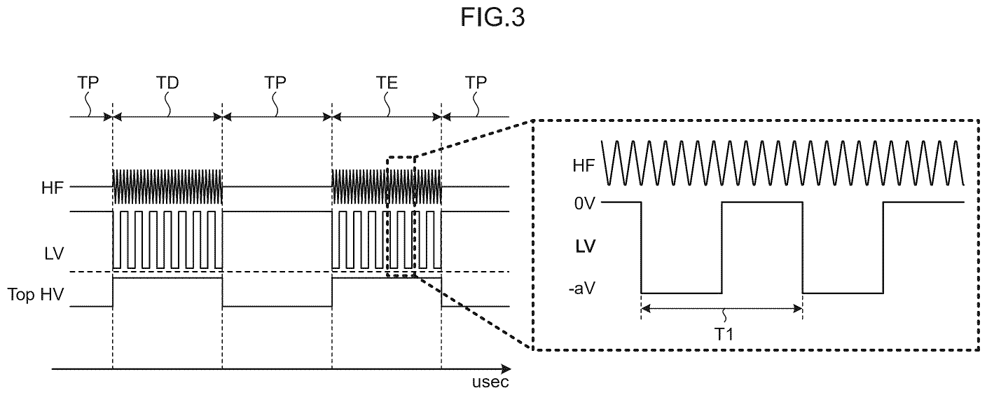

FIG. 3 is a diagram describing an example of voltage applied during etching according to the embodiment. In FIG. 3, a period TD of the first step and a period TE of the second step are illustrated. Further, in FIG. 3, periods TP are illustrated before the period TD of the first step, between the period TD of the first step and the period TE of the second step, and after the period TE of the second step. The period TP is a period in which processing gas is purged. By using prior experiment, simulation, or the like, the period TD of the first step, the period TE of the second step, and the period TP of purging are set to periods of time suitable for etching of the substrate W. The period TD and the period TE may be the same or different. Each of the pulse frequencies of the period TD and the period TE may be 1 to 100 kHz, or 5 to 50 kHz.

In FIG. 3, waveforms of power applied during etching are illustrated, and an enlarged diagram of a part is illustrated in the right side of FIG. 3. For the first DC signal, by switching to the ON state, a voltage of −a V is applied to the bottom electrode of the base 1110 or the electrode provided in the electrostatic chuck 1111.

“HF” indicates a source RF signal that the first RF generation unit 31a supplies to the top electrode of the shower head 13, the bottom electrode of the base 1110, or the bottom electrode provided in the electrostatic chuck 1111. The source RF signal is set to be a high-frequency signal having a frequency in the range of 10 MHz to 150 MHz.

“LV” indicates a pulsed first DC signal that the first DC generation unit 32a supplies to the bottom electrode of the base 1110. For the first DC signal, switching to on/off is performed at a frequency lower than the frequency of the source RF signal, and a predetermined negative voltage (−a V) is applied during the ON period. The first DC signal is transmitted at any frequency in the range of 50 kHz to 500 KHz. In the right side of FIG. 3, a case where the first DC signal is set to a frequency of, for example, 400 kHz is illustrated. The period T1 indicates one cycle in which the first DC signal is on and off. One cycle of the first DC signal is set to 2.5 μsec. When the duty ratio is set to, for example, 50%, the first DC signal is on for 1.25 μsec in one cycle.

“Top HV” indicates a pulsed second DC signal that the second DC generation unit 32b supplies to the top electrode of the shower head 13.

The controller 2 performs control such that, while purging of processing gas (period TP) is interposed, the first step (period TD) and the second step (period TE) are alternately repeated predetermined numbers of times or until a predetermined ending condition is satisfied, and etches the substrate W. Further, the controller 2 controls the power source 30 to set the duty ratio in one cycle of the first DC signal differently between the first step and the second step. For example, the controller 2 changes the duty ratio such that the ON period in which the voltage is kept in the ON state in one cycle is longer in the second step than in the first step. In the first step, the controller 2 preferably sets the ratio of the ON period in which the voltage is kept in the ON state in one cycle to 10 to 85%, more preferably 30 to 60%. Further, for the first DC signal, in the second step, the ratio of the ON period is preferably set to 15 to 90%, more preferably 50 to 80%. Thereby, when etching the substrate W according to control of the controller 2, the first DC generation unit 32a applies, to the bottom electrode of the base 1110, a first DC signal in which the ON period is set longer in one cycle in the second step than in the first step. Thereby, the plasma processing apparatus 1 according to the present embodiment can stably implement etching with a high aspect ratio. The duty ratio in one cycle of the first DC signal in each of the first step and the second step is not limited thereto. For example, the controller 2 may set the duty ratio in one cycle of the first DC signal to 1% to 99% in the first step, and may set the duty ratio in one cycle of the first DC signal to 18 to 99% in the second step. Also in this case, the plasma processing apparatus 1 according to the present embodiment can stably implement etching with a high aspect ratio.

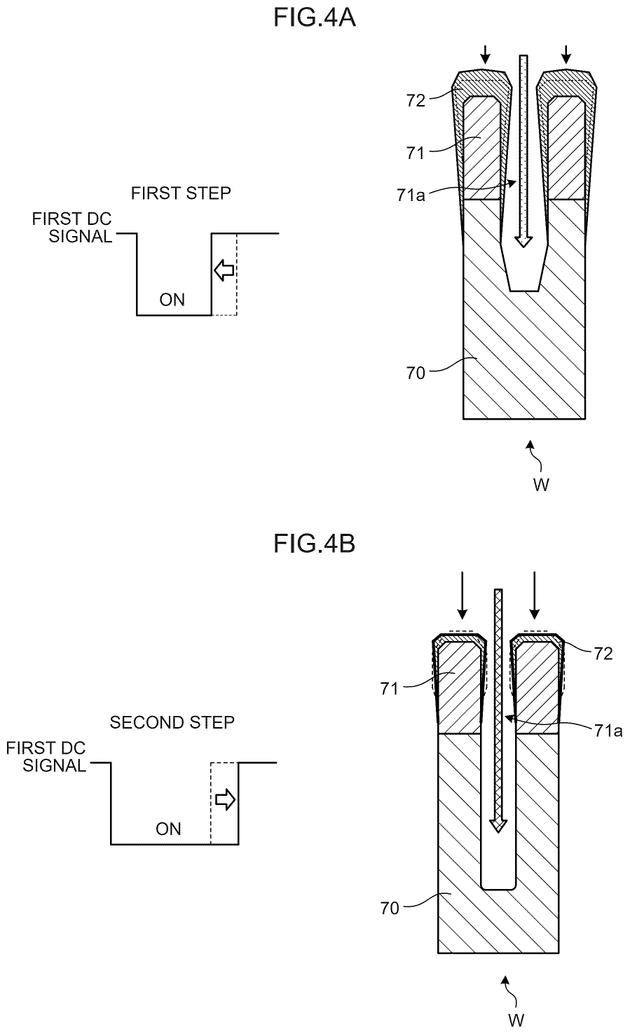

Here, a specific example of etching will now be described. FIGS. 4A and 4B are diagrams describing an example of etching according to the embodiment. In the left side of FIG. 4A, an example of the duty ratio in one cycle of the first DC signal in the first step (period TD) is illustrated. In the left side of FIG. 4B, an example of the duty ratio in one cycle of the first DC signal in the second step (period TE) is illustrated. The second step illustrated in the left side of FIG. 4B has a higher duty ratio and a longer ON period in which the voltage is kept in the ON state than the first step illustrated in the left side of FIG. 4A. For example, in the first step, the ratio (duty ratio) of the ON period in one cycle is 15%. In the second step, the ratio of the ON period in one cycle is 25%.

In the right side of FIGS. 4A and 4B, structures of a substrate W to be etched are schematically illustrated. The right side of FIG. 4A schematically illustrates the state of the substrate W in the first step (period TD). The right side of FIG. 4B schematically illustrates the state of the substrate W in the second step (period TE). In the substrate W, a film 70 to be etched is formed, and a mask film 71 is formed on the surface of the film 70. A pattern including a recess 71a is formed on the mask film 71. The film 70 is, for example, a silicon oxide film. The mask film 71 is, for example, a polysilicon film. In the first step and the second step, various gases of C₄F₆, O₂, C₄F₈, and HF₃ are supplied as processing gases from the gas supply unit 20 into the plasma processing space 10s. Depending on the flow rates of C₄F₆ and O₂ supplied from the gas supply unit 20, which of film formation and etching is dominant is changed. In the etching according to the embodiment, the flow rates of C₄F₆ and O₂ are set differently between the first step and the second step. In the first step, the flow rate of C₄F₆ is set higher to make film formation dominant, and in the second step, the relative flow rate of O₂ is set higher than the flow rate of O₂ in the first step to make etching dominant.

In the first step, by shortening the ON period in one cycle, the number of ions incident on the substrate W from the plasma can be reduced, and as a result a film 72 can be easily formed on the surface of the mask film 71. The formed film 72 functions as a protective film that protects the mask film 71 in the second step.

In the second step, by extending the ON period in one cycle, the number of ions incident on the substrate W from the plasma can be increased; as a result, the number of ions incident to the bottom of the recess 71a is increased, and the recess 71a can be vertically etched with good efficiency.

Thus, in the etching according to the embodiment, by shortening the ON period in one cycle in the first step, a film 72 can be formed on the surface of the mask film 71, and the mask film 71 can be protected in the etching of the second step. Further, in the etching according to the embodiment, by extending the ON period in one cycle in the second step, the recess 71a can be vertically etched with good efficiency.

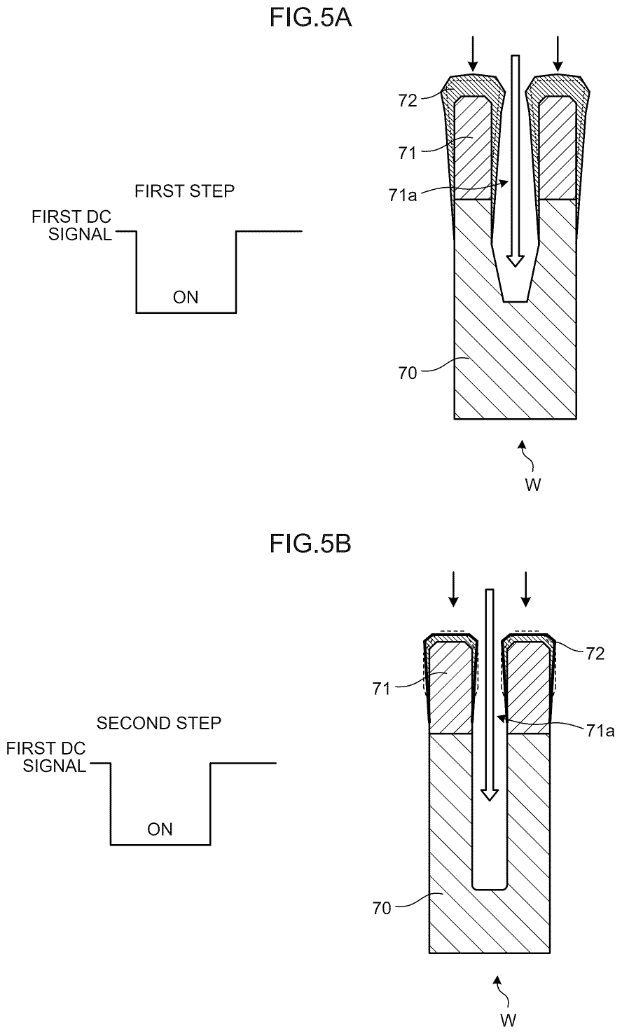

Here, a reference example will now be described. First, as a first reference example, a case where the duty ratios of the first step and the second step are set the same is described. FIGS. 5A and 5B are diagrams describing an example of etching according to the first reference example. In the left side of FIG. 5A, an example of the duty ratio in one cycle of the first DC signal in the first step (period TD) is illustrated. In the left side of FIG. 5B, an example of the duty ratio in one cycle of the first DC signal in the second step (period TE) is illustrated. In the first reference example, the duty ratio is set to 20% in both the first step and the second step.

In the right side of FIGS. 5A and 5B, structures of a substrate W to be etched are schematically illustrated like in FIGS. 4A and 4B. By setting each of the duty ratios of the first step and the second step to 20%, the number of ions incident on the substrate W from the plasma in each of the first step and the second step is between the number of ions incident on the substrate W from the plasma in the first step according to the embodiment illustrated in FIG. 4A and the number of ions incident on the substrate W from the plasma in the second step according to the embodiment illustrated in FIG. 4B. Accordingly, in the first step, the number of ions incident on the substrate W from the plasma is larger and the amount of the film 72 formed on the surface of the mask film 71 is smaller than in the first step of the embodiment illustrated in FIG. 4A. Further, in the second step, the number of ions incident on the substrate W from the plasma is smaller and the efficiency of etching the recess 71a is lower than in the second step of the embodiment illustrated in FIG. 4B. As a result, the first reference example cannot stably implement etching with a high aspect ratio as compared to the etching of the present embodiment.

Thus, it is conceivable to set the voltage level of the first DC signal differently between the first step and the second step. For example, it is conceivable to, in the second step of the etching according to the first reference example, change the voltage level of the first DC signal and apply a larger negative voltage. However, when the voltage level is thus changed, the plasma processing may not be stable.

On the other hand, in the etching according to the present embodiment, the voltage level of the first DC signal is not set differently between the first step and the second step, and the ultimate voltage is virtually increased by changing the duty ratio. Thereby, the recess 71a can be vertically etched with good efficiency while the occurrence of defects such as abnormal discharge is suppressed.

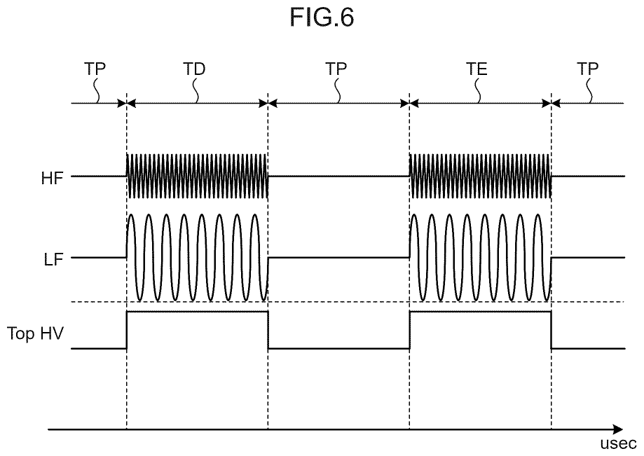

Next, as a second reference example, a case where a bias RF signal is supplied instead of the first DC signal in the first step and the second step is described. FIG. 6 is a diagram describing an example of voltage applied during etching according to the second reference example. In FIG. 6, like in FIG. 3, the period TD of the first step, the period TE of the second step, and the period TP in which processing gas is purged are illustrated. In FIG. 6, waveforms of power applied during the etching of the second reference example are illustrated.

“HF” indicates a source RF signal that the first RF generation unit 31a supplies to the bottom electrode of the base 1110. “Top HV” indicates a pulsed second DC signal that the second DC generation unit 32b supplies to the top electrode of the shower head 13.

“LF” indicates a high-frequency bias RF signal that the second RF generation unit 31b supplies to the bottom electrode of the base 1110. Since the bias RF signal is high-frequency power, its cycle is determined according to the frequency. Further, the voltage of the bias RF signal changes sinusoidally in one cycle. Thus, the ratio (duty ratio) of the ON period cannot be changed in one cycle like in the first DC signal.

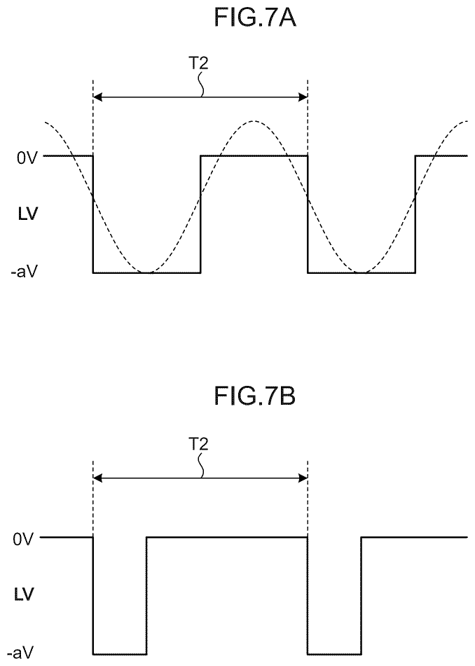

FIG. 7A is a diagram illustrating an example of the bias RF signal according to the second reference example. FIG. 7B is a diagram illustrating an example of the first DC signal according to the embodiment. In FIG. 7A, a waveform of a sine wave of the bias RF signal is illustrated. In FIG. 7B, a pulsed waveform of the first DC signal is illustrated. Each of the frequencies of the bias RF signal and the first DC signal is, for example, 400 kHz. A period T2 indicates one cycle of each of the bias RF signal and the first DC signal. In the first DC signal, the ratio of the ON period is set to 50% in one cycle. In this case, one cycle is 2.5 μsec, and the signal is on for 1.25 μsec in one cycle.

In the bias RF signal, since the voltage changes sinusoidally in one cycle, the bias cycle cannot be controlled.

On the other hand, in the first DC signal, the bias cycle can be controlled by changing the ratio of the ON period in one cycle. For example, in FIG. 7B, a case where the ratio of the ON period is set to 25% in one cycle is illustrated. In this case, the signal is on for 0.63 μsec in one cycle.

Thus, in the first DC signal, by changing the ratio (duty ratio) of the ON period in one cycle, the period in which voltage is applied to the bottom electrode of the base 1110 can be controlled more minutely. Thereby, etching like that of the present embodiment can be implemented.

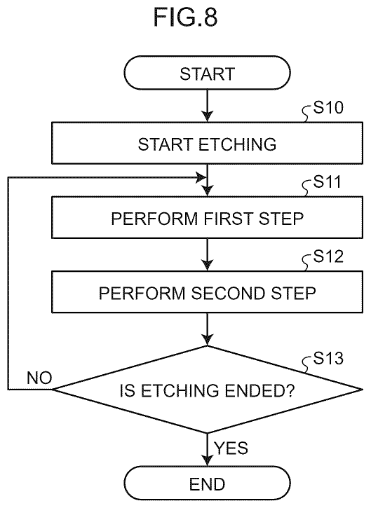

Next, a flow of processing of an etching method performed by the plasma processing apparatus 1 according to the embodiment is described. FIG. 8 is a diagram describing an example of a processing order of an etching method according to an embodiment. In the plasma processing apparatus 1, a substrate W is placed on the substrate support unit 11.

The plasma processing apparatus 1 starts etching (step S10). For example, the controller 2 controls the exhaust system 40 to exhaust the interior of the plasma processing chamber 10 to a predetermined degree of vacuum.

The plasma processing apparatus 1 performs a first step of forming a film on the substrate W (step S11). For example, the controller 2 controls the gas supply unit 20 to introduce processing gas for film formation from the gas supply unit 20. Further, the controller 2 controls the power source 30 to apply, to the bottom electrode of the base 1110, a source RF signal for plasma generation from the first RF generation unit 31a and a pulsed first DC signal from the first DC generation unit 32a. Next, the plasma processing apparatus 1 performs a second step of etching the substrate W (step S12). For example, the controller 2 controls the gas supply unit 20 to introduce processing gas for etching from the gas supply unit 20. Further, the controller 2 controls the power source 30 to apply, to the bottom electrode of the base 1110, a source RF signal for plasma generation from the first RF generation unit 31a and a pulsed first DC signal from the first DC generation unit 32a. Here, the controller 2 controls the power source 30 to set the duty ratio in one cycle of the first DC signal differently between the first step (step S11) and the second step (step S12). For example, the controller 2 changes the duty ratio such that the ON period in which the voltage is kept in the ON state in one cycle is longer in the second step than in the first step.

The plasma processing apparatus 1 determines whether to end the etching or not (step S13). For example, the controller 2 determines whether the first step and the second step have been performed predetermined numbers of times or not, or whether a predetermined ending condition is satisfied or not. In the case where the steps have been performed the predetermined numbers of times or the predetermined ending condition is satisfied, it is determined that the etching is ended. In the case where the etching is ended (step S13: Yes), the controller 2 ends the processing.

In the case where the steps have not been performed the predetermined numbers of times or the predetermined ending condition is not satisfied, and the etching is not ended (step S13: No), the procedure proceeds to step S11 above, and continues the etching.

As hereinabove, the plasma processing system (etching apparatus) according to the embodiment includes a plasma processing chamber 10 (a chamber) and a power source 30. In the interior of the plasma processing chamber 10, a substrate support unit 11 (a placing pedestal) on which a substrate W is to be mounted is provided. When etching the substrate W mounted on the substrate support unit 11 by alternately performing a first step of forming a film on the substrate W and a second step of etching the substrate W in the plasma processing chamber 10, the power source 30 periodically applies, to the substrate support unit 11, pulsed voltages in which the duty ratio in one cycle is set differently between the first step and the second step. Thereby, the plasma processing system according to the embodiment can stably implement etching with a high aspect ratio.

The power source 30 applies voltages in which the ON period in which the voltage is kept in the ON state in one cycle is set longer in the second step than in the first step. Thereby, the plasma processing system according to the embodiment can vertically etch a recess 71a having a high aspect ratio with good efficiency.

The power source 30 applies voltages of the same voltage value in a pulse manner in the first step and the second step. Thereby, the plasma processing system according to the embodiment can suppress the occurrence of defects such as abnormal discharge.

The power source 30 sets the ratio of the ON period in which the voltage is kept in the ON state in one cycle to 10% to 85% in the first step, and sets the ratio of the ON period to 15% to 90% in the second step. Thereby, the plasma processing system according to the embodiment can stably implement etching with a high aspect ratio.

The power source 30 applies voltage in a pulse manner at any frequency in the range of 50 kHz to 500 kHz. Thereby, the plasma processing system according to the embodiment can stably implement etching with a high aspect ratio.

The process of etching the substrate W includes a third step of exhausting the interior of the plasma processing chamber 10 between the first step and the second step. The power source 30 stops the application of voltage in the third step. Thereby, the plasma processing system according to the embodiment can suppress mixing of processing gases between the first step and the second step.

The substrate W has a configuration in which a film to be etched (a film 70) is formed and a mask film 71 in which a recess 71a is formed is formed on the surface of the film to be etched. The film to be etched is etched using the mask film 71 as a mask by alternately performing the first step and the second step. Thereby, the plasma processing system according to the embodiment can stably etch the film to be etched along the recess 71a formed in the mask film 71.

The film to be etched is an oxide film. The mask film is a poly mask film. The process of etching the substrate W supplies a processing gas containing C₄F₆ and O₂ into the plasma processing chamber 10, and supplies C₄F₆ into the plasma processing chamber 10 at a higher flow rate in the first step than in the second step and supplies O₂ into the plasma processing chamber 10 at a higher flow rate in the second step than in the first step. Thereby, the plasma processing system according to the embodiment can stably etch the oxide film along the recess 71a formed in the poly mask film.

Hereinabove, embodiments are described; however, it should be understood that the embodiments disclosed this time are only examples in all respects and are not restrictive. Indeed, the embodiments described above can be embodied in a variety of forms. Further, the embodiments described above may undergo omission, substitution, or alteration in various forms without departing from the claims or the spirit thereof.

For example, although in the above embodiment a case where plasma etching processing is performed on a semiconductor wafer as the substrate W is described as an example, the above embodiment is not limited thereto. The substrate W may be any substrate.

It should be understood that the embodiments disclosed this time are only examples in all respects and are not restrictive. Indeed, the above embodiments can be embodied in a variety of forms. Further, the above embodiments may undergo omission, substitution, or alteration in various forms without departing from the appended claims or the spirit thereof.

Regarding the above embodiments, the following supplementary notes are further disclosed.

According to the present disclosure, etching with a high aspect ratio can be stably implemented.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth. The present invention encompasses various modifications to each of the examples and embodiments discussed herein. According to the invention, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the invention.

In connection with the above embodiment, the following notes are further disclosed.

### (Note 1)

An etching apparatus comprising:
a chamber in an interior of which a placing pedestal on which a substrate is to be mounted is provided; and
a power source that, when etching the substrate mounted on the placing pedestal by alternately performing a first step of forming a film on the substrate and a second step of etching the substrate in the chamber, periodically applies, to the placing pedestal, pulsed voltages in which a duty ratio in one cycle is set differently between the first step and the second step.

### (Note 2)

The etching apparatus according to note 1, wherein
the power source applies voltages in which an ON period in which the voltage is kept in an ON state in the one cycle is set longer in the second step than in the first step.

### (Note 3)

The etching apparatus according to note 1 or 2, wherein
the power source applies voltages of the same voltage value in a pulse manner in the first step and the second step.

### (Note 4)

The etching apparatus according to any one of notes 1 to 3, wherein
the power source sets a ratio of an ON period in which voltage is kept in an ON state in the one cycle to 10% to 85% in the first step, and sets a ratio of the ON period to 15% to 90% in the second step.

### (Note 5)

The etching apparatus according to any one of notes 1 to 4, wherein
the power source applies voltage in a pulse manner at any frequency in a range of 50 kHz to 500 kHz.

### (Note 6)

The etching apparatus according to any one of notes 1 to 5, including
a third step of, when etching the substrate, exhausting the interior of the chamber between the first step and the second step,
wherein the power source stops application of voltage in the third step.

### (Note 7)

The etching apparatus according to any one of notes 1 to 6, wherein
the substrate has a configuration in which a film to be etched is formed and a mask film in which a recess is formed is formed on a surface of the film to be etched, and
the film to be etched is etched using the mask film as a mask by alternately performing the first step and the second step.

### (Note 8)

The etching apparatus according to any one of notes 1 to 7, wherein
the film to be etched is an oxide film, and
the mask film is a poly mask film.

### (Note 9)

The etching apparatus according to notes 8, wherein,
when etching the substrate, a processing gas containing C₄F₆ and O₂ is supplied into the chamber, and C₄F₆ is supplied into the chamber at a higher flow rate in the first step than in the second step and O₂ is supplied into the chamber at a higher flow rate in the second step than in the first step.

### (Note 10)

An etching method comprising:
a process of, in a chamber in an interior of which a placing pedestal on which a substrate is to be mounted is provided, etching the substrate mounted on the placing pedestal by alternately performing a first step of forming a film on the substrate and a second step of etching the substrate; and
a process of, during the process of etching the substrate, applying, to the placing pedestal, pulsed voltages of a predetermined frequency in which a duty ratio in one cycle is set differently between the first step and the second step.

What is claimed is:

1. An etching apparatus comprising:
a chamber in an interior of which a placing pedestal on which a substrate is to be mounted is provided; and
a power source that, when etching the substrate mounted on the placing pedestal by alternately performing a first step of forming a film on the substrate and a second step of etching the substrate in the chamber, periodically applies, to the placing pedestal, pulsed voltages in which a duty ratio in one cycle is set differently between the first step and the second step.

2. The etching apparatus according to claim 1, wherein
the power source applies voltages in which an ON period in which the voltage is kept in an ON state in the one cycle is set longer in the second step than in the first step.

3. The etching apparatus according to claim 1, wherein
the power source applies voltages of the same voltage value in a pulse manner in the first step and the second step.

4. The etching apparatus according to claim 1, wherein
the power source sets a ratio of an ON period in which voltage is kept in an ON state in the one cycle to 10% to 85% in the first step, and sets a ratio of the ON period to 15% to 90% in the second step.

5. The etching apparatus according to claim 1, wherein
the power source applies voltage in a pulse manner at any frequency in a range of 50 kHz to 500 KHz.

6. The etching apparatus according to claim 1, including
a third step of, when etching the substrate, exhausting the interior of the chamber between the first step and the second step,
wherein the power source stops application of voltage in the third step.

7. The etching apparatus according to claim 1, wherein
the substrate has a configuration in which a film to be etched is formed and a mask film in which a recess is formed is formed on a surface of the film to be etched, and
the film to be etched is etched using the mask film as a mask by alternately performing the first step and the second step.

8. The etching apparatus according to claim 7, wherein
the film to be etched is an oxide film, and
the mask film is a poly mask film.

9. The etching apparatus according to claim 8, wherein,
when etching the substrate, a processing gas containing C₄F₆ and O₂ is supplied into the chamber, and C₄F₆ is supplied into the chamber at a higher flow rate in the first step than in the second step and O₂ is supplied into the chamber at a higher flow rate in the second step than in the first step.

10. The etching apparatus according to claim 1, further comprising a gas supply configured to supply a processing gas into the chamber,
wherein at least one of a type or a flow rate of the processing gas is set differently between the first step and the second step.

11. The etching apparatus according to claim 1, wherein the chamber is a plasma processing chamber, and the power source includes an RF power source configured to supply a source RF signal for plasma generation.

12. The etching apparatus according to claim 1, wherein the pulsed voltages are negative DC voltages applied to a bottom electrode in the placing pedestal.

13. The etching apparatus according to claim 1, wherein the placing pedestal includes an electrostatic chuck and a ring assembly.

14. An etching method comprising:
a process of, in a chamber in an interior of which a placing pedestal on which a substrate is to be mounted is provided, etching the substrate mounted on the placing pedestal by alternately performing a first step of forming a film on the substrate and a second step of etching the substrate; and
a process of, during the process of etching the substrate, applying, to the placing pedestal, pulsed voltages of a predetermined frequency in which a duty ratio in one cycle is set differently between the first step and the second step.

15. The etching method according to claim 14, further comprising supplying a carbon-containing gas in the first step and a fluorine-containing gas as in the second step.

16. The etching method according to claim 14, wherein the process of etching includes generating plasma in the chamber using a source RF signal.

17. A non-transitory computer-readable medium storing instructions that, when executed by a processor of a controller in an etching apparatus having a chamber with a placing pedestal and a power source, cause the etching apparatus to:
etch a substrate mounted on the placing pedestal by alternately performing a first step of forming a film on the substrate and a second step of etching the substrate in the chamber; and
control the power source to periodically apply, to the placing pedestal, pulsed voltages in which a duty ratio in one cycle is set differently between the first step and the second step.

18. The non-transitory computer-readable medium according to claim 17, wherein the instructions further cause the etching apparatus to set an ON period in which the voltage is kept in an ON state in the one cycle longer in the second step than in the first step.

19. The non-transitory computer-readable medium according to claim 17, wherein the instructions further cause the etching apparatus to exhaust an interior of the chamber between the first step and the second step while stopping application of the pulsed voltages.

20. The non-transitory computer-readable medium according to claim 17, wherein the instructions further cause the etching apparatus to repeat the first step and the second step a predetermined number of times or until a predetermined ending condition is satisfied.
